(19) United States
(12) Patent Application Publication
(10) Pub. No.: US 2026/0088818 A1
(43) Pub. Date: Mar. 26, 2026

(54) QUANTUM COMPUTER SYSTEM

(71) Applicant: Rohde & Schwarz GmbH & Co. KG, Muenchen (DE)

(72) Inventors: Flavio HEER, Zurich (CH); Fabian PFAEFFLI, Zurich (CH); David MUELLER, Zurich (CH); Fabian SCHENKEL, Zurich (CH); Arsenii KRASNOV, Zurich (CH); Christoph RUEHLE, Zurich (CH); Remigius MOMMSEN, Zurich (CH); Tobias THIELE, Zurich (CH)

(21) Appl. No.: 18/893,160

(22) Filed: Sep. 23, 2024

(51) Int. Cl. H03K 17/92; G06N 10/40; H03K 21/08

(52) U.S. Cl. CPC H03K 17/92; G06N 10/40; H03K 21/08

(57) ABSTRACT

A quantum computer system includes a control and analysis circuit, a chip connection circuit, and a quantum computer chip including a plurality of qubits. The control and analysis circuit includes a conversion circuit, and a frontend circuit. At least one of the control and analysis circuit, the conversion circuit, the frontend circuit, the chip connection circuit, or the quantum computer chip is at least partially established as an application-specific integrated circuit, ASIC.

### FIELD OF THE DISCLOSURE

Embodiments of the present disclosure generally relate to a quantum computer system.

### BACKGROUND

Quantum computer chips are typically operated by generating electrical microwave signals in order to control individual qubits of the quantum computer chip and in order to read out quantum states of the individual qubits.

One key figure of merit of such quantum computer systems is qubit fidelity, which is a measure for the reliability or the accuracy of a read-out quantum state or of a quantum computing operation. With increasing numbers of qubits becoming available, it becomes increasingly more challenging to provide quantum computer systems that provide high qubit fidelity for all qubits.

Thus, there is a need for a quantum computer system that increases qubit fidelity.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a quantum computer system. In an embodiment, the quantum computer system comprises a control and analysis circuit, wherein the control and analysis circuit comprises a conversion circuit and a frontend circuit. The quantum computer system also comprises a chip connection circuit and a quantum computer chip comprising a plurality of qubits. The control and analysis circuit is configured to: generate a plurality of electrical signals for the plurality of qubits of the quantum computer chip; and analyze a plurality of electrical read-out signals received from the plurality of qubits of the quantum computer chip. The chip connection circuit is configured to: apply the plurality of electrical signals to the plurality of qubits of the quantum computer chip; and obtain the plurality of electrical read-out signals from the plurality of qubits of the quantum computer chip. The conversion circuit is configured to: convert the plurality of electrical signals into analog signals; and convert the electrical read-out signals received from the plurality of qubits of the quantum computer chip into digital signals. The frontend circuit is configured to: adapt a frequency of the plurality of analog signals obtained by the conversion circuit or a frequency of the plurality of electrical signals generated by the control and analysis circuit; and adapt a frequency of the electrical read-out signals received from the plurality of qubits or a frequency of the digital signals obtained by the conversion circuit. At least one of the control and analysis circuit, the conversion circuit, the frontend circuit, the chip connection circuit, or the quantum computer chip is at least partially established as an application-specific integrated circuit (ASIC).

The plurality of electrical signals generated by the control and analysis circuit for the plurality of qubits are understood to comprise electrical control signals and/or electrical read-out request signals. The electrical control signals are configured to control the respective qubits to enter a predetermined quantum state. The electrical read-out request signals are configured to initiate a read-out of the quantum states of the respective qubits.

The quantum computer system disclosed herein is based on the idea to reduce the latency between the quantum computer chip and the control and analysis circuit, for example the respective latency between the qubits and the control and analysis circuit.

In one or more embodiments, the reduction in latency is achieved, for example, by integrating at least one of the control and analysis circuit, the conversion circuit, the frontend circuit, the chip connection circuit, or the quantum computer chip into an ASIC at least partially.

Using ASICs in the quantum computer system generally provides faster operational speeds at reduced power consumption. However, this comes at the cost of missing re-programmability of individual components.

Due to the faster operational speeds, the latency between the control and analysis circuit and the qubits is reduced, which leads to a higher fidelity of the quantum states of the qubits controlled and analyzed by the control and analysis circuit. Moreover, using ASICs in the quantum computer system allows for a denser packing of circuits, which is favorable in terms of scalability of the quantum computer system with increasing numbers of qubits

In an embodiment, several components of the quantum computer system may be integrated into a common ASIC, which further reduces the latency between the control and analysis circuit and the qubits, thereby further enhancing the fidelity of the quantum states of the qubits and of the quantum computing operations performed by the quantum computer system.

According to an aspect of the present disclosure, the control and analysis circuit, for example, comprises at least one sequencer circuit. In an embodiment, the at least one sequencer circuit is configured to control a sequence of the plurality of electrical signals. In an embodiment, the conversion circuit comprises at least one digital-to-analog converter (DAC). The at least one DAC of the conversion circuit is configured to convert at least one electrical signal of the plurality of electrical signals into an analog signal. In an embodiment, the at least one sequencer circuit and the at least one DAC are integrated into a common ASIC. By integrating the at least one sequencer circuit and the at least one DAC into the common ASIC, the time necessary for generating the plurality of electrical signals and converting the plurality of electrical signals into analog signals that can be applied to the quantum computer chip is reduced significantly. Thus, the latency between the control and analysis circuit and the qubits is further reduced.

In an embodiment, the control and analysis circuit comprises at least one sequencer circuit. The at least one sequencer circuit is configured to control a sequence of analysis of the plurality of electrical read-out signals. In an embodiment, the conversion circuit comprises at least one analog-to-digital converter (ADC). The at least one ADC is configured to convert at least one electrical read-out signal of the plurality of electrical read-signals into a digital signal. In an embodiment, the at least one sequencer circuit and the at least one ADC are integrated into a common ASIC. By integrating the at least one sequencer circuit and the at least one ADC into the common ASIC, the time necessary for converting the plurality of electrical read-out signals into digital signals and analyzing the resulting digital electrical read-out signals is reduced significantly. Thus, the latency between the control and analysis circuit and the qubits is further reduced.

According to another aspect of the present disclosure, the at least one sequencer circuit, for example, is configured to control a sequence of analysis of the plurality of electrical read-out signals. In an embodiment, the conversion circuit comprises at least one analog-to-digital converter (ADC). The at least one ADC is configured to convert at least one electrical read-out signal of the plurality of electrical read-signals into a digital signal. In an embodiment, the at least one sequencer circuit, the at least one DAC, and the at least one ADC are integrated into a common ASIC. By integrating the at least one sequencer circuit and the at least one DAC into the common ASIC, the time necessary for generating the plurality of electrical signals and converting the plurality of electrical signals into analog signals that can be applied to the quantum computer chip is reduced significantly. Moreover, by integrating the at least one sequencer circuit and the at least one ADC into the common ASIC, the time necessary for converting the plurality of electrical read-out signals into digital signals and analyzing the resulting digital electrical read-out signals is reduced significantly. Thus, integrating all of the at least one sequencer circuit, the at least one DAC, and the at least one ADC into the common ASIC reduces the latency between the control and analysis circuit and the qubits significantly.

In an embodiment, reducing the latency between transmitting the read-out request signals generated by the control and analysis circuit to the qubits and receiving the corresponding read-out signals from the qubits is important for a plurality of use cases, such as active qubit reset.

In an embodiment, the control and analysis circuit may comprise at least one waveform memory circuit. The at least one waveform memory circuit is configured to play back the at least one electrical signal of the plurality of electrical signals at least partially. In an embodiment, the conversion circuit comprises at least one digital-to-analog converter (DAC). The at least one DAC is configured to convert the at least one electrical signal played back by the at least one waveform memory circuit into an analog signal. In an embodiment, the at least one waveform memory circuit and the at least one DAC are integrated into a common ASIC. By integrating the at least one waveform memory circuit and the at least one DAC into the common ASIC, the time necessary for generating the plurality of electrical signals and converting the plurality of electrical signals into analog signals that can be applied to the quantum computer chip is reduced significantly. Thus, the latency between the control and analysis circuit and the qubits is further reduced.

In another embodiment, the control and analysis circuit comprises at least one controller circuit. The at least one controller circuit is configured to select at least one electrical signal of the plurality of electrical signals to be played back by the at least one waveform memory circuit. The at least one controller circuit provides a possibility to adapt a sequence of the electrical signals applied to the quantum computer chip even when the at least one sequencer circuit described above is integrated into an ASIC and thus is not re-programmable by itself.

For example, the controller circuit may be established as or comprise a field-programmable gate array, a central processing unit (CPU), and/or like processor circuits.

According to an aspect of the present disclosure, the at least one controller circuit, for example, is configured to write the at least one electrical signal of the plurality of electrical signals into the at least one waveform memory circuit. Accordingly, the at least one controller circuit provides a possibility to adapt the electrical signals applied to the quantum computer chip even when the at least one sequencer circuit described above is integrated into an ASIC and thus is not re-programmable by itself.

In an embodiment, the chip connection circuit may be integrated into an ASIC. Thus, the time necessary for applying the electrical signals to the qubits as well as the time necessary for obtaining the electrical read-out signals from the qubits is reduced, thereby further reducing the latency between the control and analysis circuit and the qubits.

Moreover, integrating the chip connection circuit into an ASIC allows for an increased density of electrical connections that apply the electrical signal generated by the control and analysis circuit to the qubits and that obtain the electrical read-out signals from the qubits. This further enhances the scalability of the quantum computer system with increasing numbers of qubits.

An aspect of the present disclosure provides that the frontend circuit, for example, is integrated into an ASIC. Thereby, the time necessary for adapting the frequency of the electrical signals and/or of the electrical read-out signals is reduced, thereby further reducing the latency between the control and analysis circuit and the qubits.

According to another aspect of the present disclosure, the control and analysis circuit, for example, comprises at least one sequencer circuit. In an embodiment, the at least one sequencer circuit is configured to control a sequence of the plurality of electrical signals and/or a sequence of analysis of the plurality of electrical read-out signals, wherein the at least one sequencer circuit is integrated into an ASIC. By integrating the at least one sequencer circuit into an ASIC, the time necessary for generating the plurality of electrical signals and/or the time necessary for analyzing the plurality of electrical read-out signals is reduced. Thus, the latency between the control and analysis circuit and the qubits is further reduced.

In another, the quantum computer chip comprises an ASIC connecting the plurality of qubits to the chip connection circuit. This way, the time necessary for applying the electrical signals to the qubits as well as the time necessary for obtaining the electrical read-out signals from the qubits is reduced, thereby reducing the latency between the control and analysis circuit and the qubits.

Moreover, the ASIC connecting the plurality of qubits to the chip connection circuit allows for an increased density of electrical connections that connect the qubits to the chip connection circuit. This further enhances the scalability of the quantum computer system with increasing numbers of qubits.

A further aspect of the present disclosure provides that the control and analysis circuit, for example, comprises at least one clock counter circuit. In an embodiment, the at least one clock counter circuit is integrated into an ASIC. Integrating the clock counter circuit into the ASIC ensures a highly precise clock count that can be used by other components or other circuits of the control and analysis circuit.

In an embodiment, the control and analysis circuit may comprise a plurality of sequencer circuits and a plurality of clock counter circuits, wherein each clock counter circuit is connected with one sequencer circuit of the plurality of sequencer circuits. Accordingly, each clock counter circuit provides a clock count for one of the sequencer circuits. By synchronizing the plurality of clock counter circuits, it is ensured that the sequence of electrical signals controlled by the plurality of sequencer circuits and/or the sequence of analysis of the plurality of electrical read-out signals are/is properly synchronized. In other words, it is ensured that each electrical signal is generated at the correct time and/or that each electrical read-out signal is analyzed at the correct time.

For example, the plurality of clock counter circuits may be synchronized via a synchronization signal that is provided by a suitable synchronization interface.

In another embodiment, the at least one clock counter circuit is integrated into the ASIC may be a wall clock counter. Accordingly, the at least one clock counter circuit being integrated into the ASIC is configured to provide a wall clock count to other components or the other circuits of the control and analysis circuit, for example to at least one sequencer circuit connected to the at least one clock counter circuit.

According to an aspect of the present disclosure, at least two of the control and analysis circuit, the conversion circuit, the frontend circuit, or the chip connection circuit, for example, are integrated into a common ASIC at least partially. By integrating two or more of the circuits described above into a single ASIC, the latency between the control and analysis circuit and the qubits is reduced even further.

Of course, it is also possible to integrate at least three or more of the control and analysis circuit, the conversion circuit, the frontend circuit, or the chip connection circuit into a common ASIC.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a quantum computer system according to an embodiment of the present disclosure;

FIG. 2 schematically shows an example of a control and analysis circuit of the quantum computer system of FIG. 1 in more detail; and

FIG. 3 schematically shows an example of a quantum computer chip of the quantum computer system of FIG. 1 in more detail.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

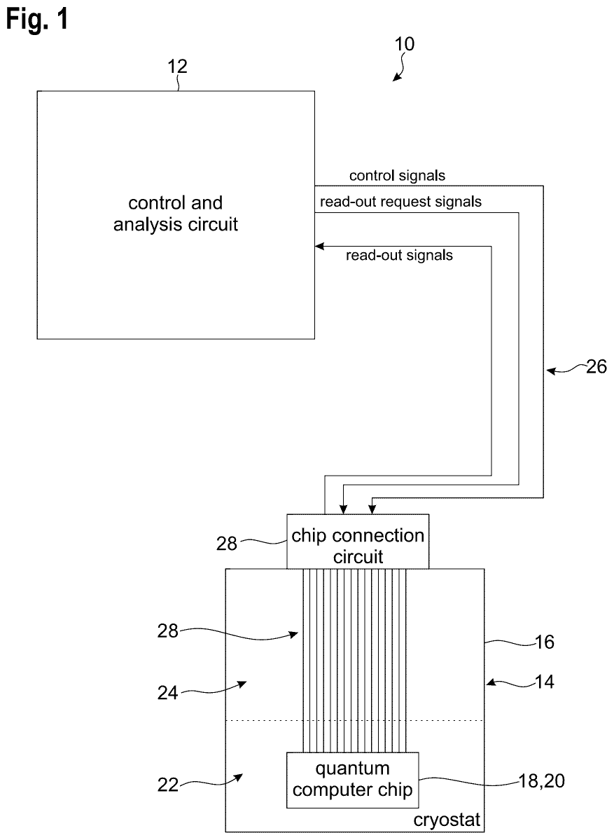

FIG. 1 schematically shows a quantum computer system 10 according to an embodiment of the present disclosure. As shown in FIG. 1, the quantum computer system 10 comprises a control and analysis circuit 12 and a cryostat 14 having a housing 16. Within the housing 16 of the cryostat 14, a quantum computer chip 18 having a plurality of qubits 20 is arranged.

For example, the cryostat 14 may have a first temperature zone 22 and at least a second temperature zone 24, wherein the quantum computer chip 18 is arranged in the first temperature zone. Therein, a temperature of the first temperature zone 22 may be lower than a temperature of the second temperature zone 24.

It is noted that, of course, the cryostat 14 comprises cooling equipment that is configured to reduce a temperature within the cryostat to an operating temperature of the qubits 20. In an embodiment, the cryostat 14 may have several pieces of cooling equipment in the different temperature zones 22, 24, wherein the different pieces of cooling equipment successively reduce the temperature of the respective zone. For ease of illustration, the cooling equipment is not shown in FIG. 1.

In general, the control and analysis circuit 12 is configured to generate a plurality of electrical signals for the plurality of qubits 20 of the quantum computer chip 18. In an embodiment, the electrical signal generated by the control and analysis circuit 12 comprise electrical control signals and/or electrical read-out request signal. The control signals may be configured to control the respective qubits 20 to enter a predetermined quantum state. In other words, the control signals are configured to set quantum states of the respective qubits 20. The read-out request signals are configured to initiate a read-out of the quantum states of the respective qubits 20.

In an embodiment, the electrical signals may be radio frequency (RF) signals having a frequency in the microwave regime, e.g. 300 MHz or higher.

In an embodiment, the control and analysis circuit 12 is configured to analyze a plurality of electrical read-out signals received from the plurality of qubits 20 in response to the electrical read-out request signals applied to the qubits 20.

Between the control and analysis circuit 12 and the cryostat 14, a data connection 26 is provided. For example, the data connection 26 may comprise at least one electrical conductor, for example a plurality of electrical conductors. In an embodiment, the data connection 26 may comprise a plurality of electrically conductive cables, such as copper cables.

In general, the data connection 26 is configured to transmit the electrical signals generated by the control and analysis circuit 12 to the cryostat 14. This allows, for example, the control and analysis circuit 12 to be in one location, such as a laboratory office, and the cryostat 14 to be in another location, such as another laboratory room. The data connection 26 is further configured to transmit the electrical read-out signals obtained from the qubits 20 from the cryostat 14 to the control and analysis circuit 12.

In the embodiment of FIG. 1, the quantum computer system 10 further comprises a chip connection circuit 28 that connects the quantum computer chip 18 to the data connection 26. In general, the chip connection circuit 28 is configured to apply the electrical signals generated by the control and an analysis circuit 12 to the qubits 20. Moreover, the chip connection circuit 28 is configured to obtain the electrical read-out signals from the qubits 20.

In one or more embodiments, the chip connection circuit 28 may at least partially be integrated into an ASIC. In an embodiment, the chip connection circuit 28 may comprise an ASIC or may be established as an ASIC.

It is noted that while the chip connection circuit 28 is shown to be arranged partially outside of the cryostat 14 in FIG. 1, it is also possible that the chip connection circuit 28 may be arranged completely within the cryostat 14.

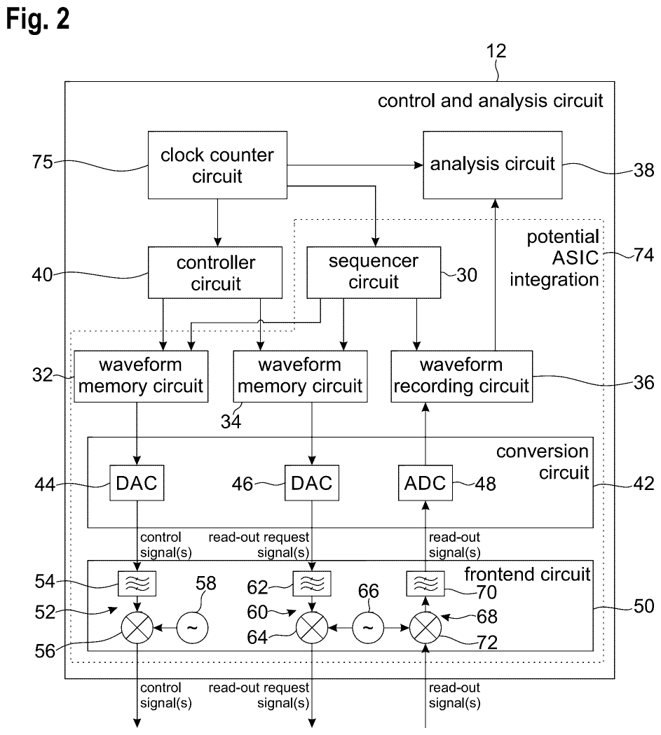

FIG. 2 shows an example embodiment of the control and analysis circuit 12 in more detail. In the embodiment of FIG. 2, the control and analysis circuit 12 comprises a sequencer circuit 30, a first waveform memory circuit 32, a second waveform memory circuit 34, and a waveform recording circuit 36. The first waveform memory circuit 32 is configured to store and play back at least one control signal. The second waveform memory circuit 34 is configured to store and playback at least one read-out request signal.

The sequencer circuit 30 is configured to control a sequence of the at least one control signal and of the at least one read-out request signal being played back by the first waveform memory circuit 32 and by the second waveform memory circuit 34, respectively. The waveform recording circuit 36 is configured to record, i.e. at least temporarily store, electric read-out signals received from the qubits 20. The sequencer circuit 30 further is configured to control a sequence of the read-out signals being analyzed by an analysis circuit 38 that is provided downstream of the waveform recording circuit 36.

In an embodiment, the quantum states of the qubits 20 may be determined by the analysis circuit 38 based on the electrical read-out signals, and corresponding computational data may be generated by the analysis circuit 38 based on the quantum states determined.

In an embodiment, the control and analysis circuit 12 further comprises a controller circuit 40 that is connected to both the first waveform memory circuit 32 and the second waveform memory circuit 34. For example, the controller circuit 40 may be established as or comprise a field-programmable gate array, a central processing unit (CPU), or like processor circuits.

In general, the controller circuit 40 is configured to select the electrical signals, i.e., the at least one control signal and/or the at least one readout request signal, to be played back by the first waveform memory circuit 32 and/or the second waveform memory circuit 34. In an embodiment, the controller circuit 40 may be configured to write the selected electrical signals into the first waveform memory circuit 32 and/or into the second waveform memory circuit 34.

For example, the controller circuit 40 may be configured to write the selected at least one control signal into the first waveform memory circuit 32. Alternatively or additionally, the controller circuit 40 may be configured to write the selected at least one read-out request signal into the second waveform memory circuit 34.

In an embodiment, the control and analysis circuit 12 further comprises a conversion circuit 42 that is provided downstream of the waveform memory circuits 32, 34 and upstream of the waveform recording circuit 36. In an embodiment, the conversion circuit 42 comprises at least one first digital-to-analog converter (DAC) 44 that is connected to the first waveform memory circuit 32 downstream of the first waveform memory circuit 32. The at least one first DAC 44 is configured to convert the at least one control signal played back by the first waveform memory circuit 32 into an analog signal.

In an embodiment, the conversion circuit 42 further comprises at least one second DAC 46 that is connected to the second waveform memory circuit 34 downstream of the second waveform memory circuit 34. The at least one second DAC 46 is configured to convert the at least one read-out request signal played back by the second waveform memory circuit 34 into an analog signal.

In an embodiment, the conversion circuit 42 further comprises at least one analog-to-digital converter (ADC) 48 that is connected to the waveform recording circuit 36 upstream of the waveform recording circuit 36. The at least one ADC 48 is configured to convert the read-out signals received from the qubits 20 into digital signals.

In an embodiment, the control and analysis circuit 12 further comprises a frontend circuit 50. In the example embodiment the control and analysis circuit 12 shown in FIG. 2, the frontend circuit 50 is configured to adapt a respective frequency of the electrical signals generated by the control and analysis circuit 12 as well as a respective frequency of the electrical read-out signals received form the qubits 20.

For example, the frontend circuit 50 comprises at least one first mixer circuit 52 that is connected to the at least one first DAC 44 downstream of the at least one first DAC 44. In an embodiment, the at least one first mixer circuit 52 comprises a first filter circuit 54, a first mixer sub-circuit 56, and a first local oscillator circuit 58.

The first mixer sub-circuit 56 mixes the respective control signal played back by the first waveform memory circuit 32 with a local oscillator signal generated by the first local oscillator circuit 58, thereby shifting a frequency of the respective control signal. In an embodiment, the frequency of the respective control signal may be shifted, for example increased, to a frequency that is suitable for controlling the qubits 20.

In an embodiment, the frontend circuit 50 further comprises at least one second mixer circuit 58 that is connected to the at least one second DAC 46 downstream of the at least one second DAC 46. The at least one second mixer circuit 60 comprises a second filter circuit 62, a second mixer sub-circuit 64, and a second local oscillator circuit 66.

The second mixer sub-circuit 64 mixes the respective read-out request signal played back by the second waveform memory circuit 34 with a local oscillator signal generated by the second local oscillator circuit 66, thereby shifting a frequency of the respective read-out request signal. In an embodiment, the frequency of the respective read-out request signal may be shifted, for example increased, to a frequency that is suitable for reading out a quantum state of the qubits 20.

In an embodiment, the frontend circuit 50 further comprises at least one third mixer circuit 68 that is connected to the at least one ADC 48 upstream of the at least one ADC 48. The at least one third mixer circuit 68 comprises a third filter circuit 70 and a third mixer sub-circuit 72. In the example embodiment shown in FIG. 2, the second local oscillator circuit 66 is shared between the second mixer circuit 60 and the third mixer circuit 68. In an embodiment, the second local oscillator circuit 66 is connected to both the second mixer sub-circuit 64 and the third mixer sub-circuit 72.

The third mixer sub-circuit 72 mixes the respective read-out signal played received from the qubits 20 with the local oscillator signal generated by the second local oscillator circuit 66, thereby shifting a frequency of the respective read-out signal. In an embodiment, the frequency of the respective read-out signal may be shifted, for example decreased, to a frequency that is suitable for processing by the conversion circuit 42, the waveform recording circuit 36, and the analysis circuit 38.

In the example embodiment described above, the frontend circuit 50 is arranged in the analog domain, i.e. the frontend circuit 50 processes and adapts the frequencies of analog signals. However, it is to be understood that the frontend circuit 50 may alternatively be arranged in the digital domain, namely between the waveform memory circuits 32, 34 as well as the waveform recording circuit 36 on one hand and the conversion circuit 42 on the other hand.

In this case, the first mixer circuit 52 is configured to adapt a frequency of the respective control signal played back by the first waveform memory circuit 32 prior to conversion by the first DAC 44. Likewise, the second mixer circuit 60 is configured to adapt a frequency of the respective read-out request signal played back by the second waveform memory circuit 34 prior to conversion by the second DAC 46. The third mixer circuit is configured to adapt a frequency of the respective digital read-out signal obtained by the ADC 48.

In an embodiment, the control and analysis circuit 12 may further comprise a clock counter circuit 75, which may be established as an ASIC. In general, the clock counter circuit 75 is configured to generate a clock signal or a clock count for other components of the control and analysis circuit 12. For example, the clock counter circuit 75 may be a wall clock counter.

In the example embodiment shown in FIG. 2, the clock counter circuit 75 is connected to the analysis circuit 38, the sequencer circuit 30, and the controller circuit 40. Accordingly, the clock counter circuit 75 may provide the clock count generated to the analysis circuit 38, the sequencer circuit 30, and the controller circuit 40. However, it is to be understood that the clock counter circuit 75 may be connected to further components and thus may provide the clock count to further components, such as the waveform memory circuits 32, 34, the waveform recording circuit 36, the conversion circuit 42, and/or the frontend circuit 50.

For example, the control and analysis circuit 12 may comprise a plurality of sequencer circuits and a plurality of clock counter circuits, wherein each clock counter circuit is connected with one sequencer circuit of the plurality of sequencer circuits. Accordingly, each clock counter circuit provides a clock count for one of the sequencer circuits. By synchronizing the plurality of clock counter circuits, it is ensured that the sequence of electrical signals controlled by the plurality of sequencer circuits and/or the sequence of analysis of the plurality of electrical read-out signals are/is properly synchronized. In other words, it is ensured that each electrical signal is generated at the correct time and/or that each electrical read-out signal is analyzed at the correct time.

For example, the plurality of clock counter circuits may be synchronized via a synchronization signal that is provided by a suitable synchronization interface. In an embodiment, the control and analysis circuit 12 may comprise a central lead clock reference circuit and/or a central lead wall clock circuit generating the synchronization signal.

One or several further components of the control and analysis circuit 12 may be established as an ASIC, be partially integrated into an ASIC, and/or be integrated into a common ASIC, as is indicated by the “potential ASIC integration” box 74 in FIG. 2. As is illustrated in FIG. 2, individual, several, or all of the components inside the box 74 may at least partially be established by an ASIC.

In an embodiment, an arbitrary subset of the sequencer circuit 30, the first waveform memory circuit 32, the second waveform memory circuit 34, the waveform recording circuit 36, the at least one first DAC 44, the at least one second DAC 46, and the at least one ADC 48 may be integrated into a common ASIC. Therein, the term “arbitrary subset” is understood to denote at least one of these components, at least two of these components, etc., up to all of these components.

For example, the first waveform memory circuit 32 and the at least one first DAC 44 may be integrated into a common ASIC. Alternatively or additionally, the second waveform memory circuit 34 and the at least one second DAC 46 may be integrated into a common ASIC. Alternatively or additionally, the waveform recording circuit 36 and the at least one ADC 48 may be integrated into a common ASIC.

In a certain example embodiment, the sequencer circuit 30, the first waveform memory circuit 32, and the second waveform memory circuit 34 may be integrated into a common ASIC. In a further example embodiment, the sequencer circuit 30, the first waveform memory circuit 32, the second waveform memory circuit 34, the at least one first DAC 44, and the at least one second DAC 46 may be integrated into a common ASIC.

As another example embodiment, the sequencer circuit 30, and the waveform recording circuit 36 may be integrated into a common ASIC. According to another example embodiment, the sequencer circuit 30, the waveform recording circuit 36, and the at least one ADC 48 may integrated into a common ASIC.

In a further example embodiment, the sequencer circuit 30, the first waveform memory circuit 32, the second waveform memory circuit 34, and the waveform recording circuit 36 may be integrated into a common ASIC. As another example, the sequencer circuit 30, the first waveform memory circuit 32, the second waveform memory circuit 34, the waveform recording circuit 36, the at least one first DAC 44, the at least one second DAC 46, and the at least one ADC 48 may integrated into a common ASIC.

Alternatively or additionally to the examples described above, the conversion circuit 42 may be integrated into an ASIC. Alternatively or additionally to the examples described above, the frontend circuit 50 may be integrated into an ASIC.

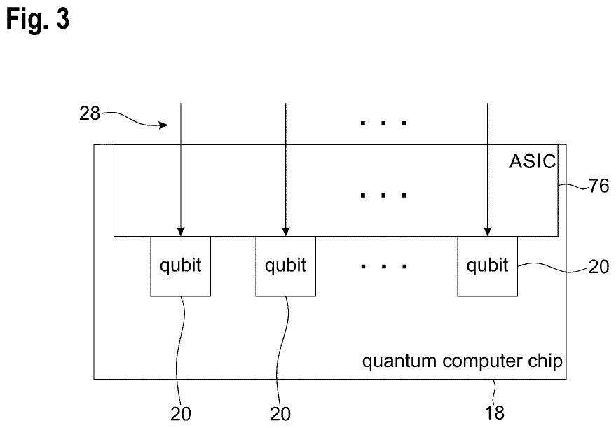

FIG. 3 schematically shows an example embodiment of the quantum computer chip 18 in more detail. As is illustrated in FIG. 3, the quantum computer chip 18 may comprise an ASIC 76 that connects the individual qubits 20 to the chip connection circuit 28.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the control and analysis circuit 12, the chip connection circuit 28, the quantum computer chip 18, etc., referenced above include circuitry programmed to carry out some of, or all of, the functionality or methodology disclosed herein. In an embodiment, one or more computer-readable media associated with or accessible by such circuitry contains computer readable instructions embodied thereon that, when executed by such circuitry, cause the component or circuity to perform some of, or all of, the functionality or methodology disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A quantum computer system, the quantum computer system comprising:
a control and analysis circuit, wherein the control and analysis circuit comprises a conversion circuit and a frontend circuit;
a chip connection circuit; and
a quantum computer chip comprising a plurality of qubits,
wherein the control and analysis circuit is configured to:
generate a plurality of electrical signals for the plurality of qubits of the quantum computer chip; and
analyze a plurality of electrical read-out signals received from the plurality of qubits of the quantum computer chip,
wherein the chip connection circuit is configured to:
apply the plurality of electrical signals to the plurality of qubits of the quantum computer chip; and obtain the plurality of electrical read-out signals from the plurality of qubits of the quantum computer chip,
wherein the conversion circuit is configured to:
convert the plurality of electrical signals into analog signals; and
convert the electrical read-out signals received from the plurality of qubits of the quantum computer chip into digital signals,
wherein the frontend circuit is configured to:
adapt a frequency of the plurality of analog signals obtained by the conversion circuit or a frequency of the plurality of electrical signals generated by the control and analysis circuit; and adapt a frequency of the electrical read-out signals received from the plurality of qubits or a frequency of the digital signals obtained by the conversion circuit, and
wherein at least one of the control and analysis circuit, the conversion circuit, the frontend circuit, the chip connection circuit, or the quantum computer chip is at least partially established as an application-specific integrated circuit (ASIC).

2. The quantum computer system of claim 1, wherein the control and analysis circuit comprises at least one sequencer circuit, the at least one sequencer circuit being configured to control a sequence of the plurality of electrical signals, wherein the conversion circuit comprises at least one digital-to-analog converter, DAC, the at least one DAC being configured to convert at least one electrical signal of the plurality of electrical signals into an analog signal, and wherein the at least one sequencer circuit and the at least one DAC are integrated into a common ASIC.

3. The quantum computer system of claim 1, wherein the control and analysis circuit comprises at least one sequencer circuit, the at least one sequencer circuit being configured to control a sequence of analysis of the plurality of electrical read-out signals, wherein the conversion circuit comprises at least one analog-to-digital converter, ADC, the at least one ADC being configured to convert at least one electrical read-out signal of the plurality of electrical read-signals into a digital signal, and wherein the at least one sequencer circuit and the at least one ADC are integrated into a common ASIC.

4. The quantum computer system of claim 2, wherein the at least one sequencer circuit is configured to control a sequence of analysis of the plurality of electrical read-out signals, wherein the conversion circuit comprises at least one analog-to-digital converter, ADC, the at least one ADC being configured to convert at least one electrical read-out signal of the plurality of electrical read-signals into a digital signal, and wherein the at least one sequencer circuit, the at least one DAC, and the at least one ADC are integrated into a common ASIC.

5. The quantum computer system of claim 2, wherein the control and analysis circuit comprises at least one waveform memory circuit, wherein the at least one waveform memory circuit is configured to play back the at least one electrical signal of the plurality of electrical signals at least partially, wherein the conversion circuit comprises at least one digital-to-analog converter, DAC, the at least one DAC being configured to convert the at least one electrical signal played back by the at least one waveform memory circuit into an analog signal, and wherein the at least one waveform memory circuit and the at least one DAC are integrated into a common ASIC.

6. The quantum computer system of claim 5, wherein the control and analysis circuit comprises at least one controller circuit wherein the at least one controller circuit is configured to select at least one electrical signal of the plurality of electrical signals to be played back by the at least one waveform memory circuit.

7. The quantum computer system of claim 6, wherein the at least one controller circuit is configured to write the at least one electrical signal of the plurality of electrical signals into the at least one waveform memory circuit.

8. The quantum computer system of claim 1, wherein the chip connection circuit is integrated into an ASIC.

9. The quantum computer system of claim 1, wherein the frontend circuit is integrated into an ASIC.

10. The quantum computer system of claim 1, wherein the control and analysis circuit comprises at least one sequencer circuit, the at least one sequencer circuit being configured to control a sequence of the plurality of electrical signals and/or a sequence of analysis of the plurality of electrical read-out signals, wherein the at least one sequencer circuit is integrated into an ASIC.

11. The quantum computer system of claim 1, wherein the quantum computer chip comprises an ASIC connecting the plurality of qubits to the chip connection circuit.

12. The quantum computer system of claim 1, wherein the control and analysis circuit comprises at least one clock counter circuit, the at least one clock counter circuit being integrated into an ASIC.

13. The quantum computer system of claim 12, wherein the at least one clock counter circuit being integrated into the ASIC is a wall clock counter.

14. The quantum computer system of claim 1, wherein at least two of the control and analysis circuit, the conversion circuit, the frontend circuit, or the chip connection circuit are integrated into a common ASIC at least partially.
